(19) United States
(12) Patent Application Publication
(10) Pub. No.: US 2006/0209990 A1
(43) Pub. Date: Sep. 21, 2006

(54) Communication semiconductor integrated circuit device incorporating a PLL circuit therein

(76) Inventors: Tamotsu Takahashi, Kitatachibana (JP); Taizo Yamawaki, Tokyo (JP); Robert Astle Henshaw, Suffolk (GB)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/374,125

(22) Filed: Mar. 14, 2006

(30) Foreign Application Priority Data
Mar. 14, 2005 (GB) 0505230.3

(51) Int. Cl. H03D 3/24

(52) U.S. Cl. 375/327

(57) ABSTRACT

A communication semiconductor high-frequency IC device includes an offset-PLL transmission circuit. The device does not require an intermediate-frequency voltage controlled oscillator (IFVCO) to generate an intermediate-frequency (IF) signal and can modulate and demodulate transmission and reception signals of desired frequency bands without a complicated frequency division control circuit. An RF-PLL includes an RFVCO to generate a local oscillation signal shared by a transmission circuit and receiving circuit; controllers, capable of dividing a signal by a frequency dividing ratio represented by an integer, as a frequency divider to divide a reference oscillation signal (φref) and a frequency divider to divide its own oscillation signal (φFB); and a frequency divider to divide a local oscillation signal (φRF) from the RF-PLL to generate an IF signal (φIF) necessary for the transmission circuit. The frequency dividing ratios of the dividers are changed according to a transmission or reception frequency.

### BACKGROUND OF THE INVENTION

The present invention relates to a technique effectively applicable to a high-frequency semiconductor integrated circuit device incorporating a Phase Locked Loop (PLL) circuit including a Voltage Controlled Oscillator (VCO), for example, to a technique effectively applicable to a communication semiconductor integrated circuit device to conduct operations such as an operation to modify and to up-covert a transmission signal in a wireless communication device, for example, a portable telephone.

In the wireless communication system such as a portable telephone, a communication semiconductor integrated circuit device (to be referred to as a high-frequency IC device hereinbelow) is used to conduct operations such as an operation in which a reception signal is combined with a high-frequency local oscillation signal to down-convert or up-convert the signal, an operation to modulate a transmission signal, and an operation to demodulate a reception signal. There is known an offset PLL system for use with the high-frequency IC device in which transmission I and Q signals are modulated through quadrature modulation using a carrier having an intermediate frequency and a feedback signal from an output port of a transmission VCO is mixed with a high-frequency oscillation signal from an radio-frequency (RF) VCO to down-convert the signal into a signal of an intermediate frequency corresponding to the frequency difference (offset). Thereafter, the phase of the signal is compared with that of the modulated signal after the quadrature modulation to control the transmission VCO according to the phase difference therebetween.

The high-frequency IC device of the offset PLL system requires, in addition to the transmission VCO and the RFVCO, an intermediate frequency (IF) VCO to generate a carrier having an intermediate frequency. Since the VCO occupies a relatively large area, the conventional high-frequency IC device uses a VCO externally disposed as an external unit with respect to the device in many cases. However, when such an externally disposed VCO is used, the number of parts increases and it is difficult to reduce the high-frequency IC device in size. To overcome this difficulty, there has been proposed a technique to incorporate the VCO in a chip of the IC device. However, when the chip incorporates three VCOs described above, the chip size increases and the chip cost resultantly soars.

On the other hand, the portable telephones of recent years include a dual-band portable telephone capable of handling signals of two frequency bands including, for example, a band of 880 megaherz (MHz) to 915 MHz for Global System for Mobile Communication (GSM) and a band of 1710 MHz to 1785 MHz for a Digital Cellular System (DCS). A need exists recently for a triple-band portable telephone capable of handling signals of the bands for GSM and the DSC and signals of a band from 1850 MHz to 1915 MHz for a Personal Communication System (PCS). It is expected that portable telephones are desired to be capable of coping with much more communication systems in the future. For a voltage controlled oscillator circuit (VCO) used in such a portable telephone capable of coping with a plurality of communication systems, a wide oscillation frequency range is required.

In this situation, if it is desired to cope with all frequencies using one voltage controlled circuit, sensitivity (to be referred to as control sensitivity hereinbelow) of the oscillation frequency with respect to the control voltage of the VCO becomes higher. This leads to a disadvantage of weakness with respect to external noise and a variation in the power source voltage. To overcome this difficulty, there has been proposed a technique in which a change-over operation is conducted to assign one of a plurality of frequencies (for example, 16 frequencies) to the VCO in operation to thereby reduce the VCO control sensitivity while keeping a desired oscillation frequency range. Reference is to be made to, for example, EP-A-1,444,784 published 11 Aug. 2004 (corresponding to JP-A-2003-152535).

### SUMMARY OF THE INVENTION

To reduce the chip size of a high-frequency IC device including VCOs, there exists a technique to reduce the number of VCOs by using a shared VCO for an RFVCO with an IFVCO. Specifically, the frequency of the oscillation signal from the RFVCO is divided to generate a signal of an intermediate frequency to resultantly remove the IFVCO from the device. In this connection, if it is only necessary to set an integer as the frequency dividing ratio to a variable frequency divider (counter) in the PLL including the VCO, the ratio can be set by a relatively simple logic circuit. However, when an integer is set as the frequency dividing ratio, the oscillation frequency change-over can be conducted only in an interval of a frequency substantially equal to the frequency of the reference signal. On the other hand when a shared VCO is used for RFVCO and IFVCO, it is required to conduct the change-over of the oscillation frequency in an interval of a more precise frequency. Therefore, the counter is required to be operated with a frequency dividing ratio including a decimal.

However, when it is desired to incorporate a logic circuit to set a frequency dividing ratio including a decimal in a high-frequency IC device, the logic circuit becomes greater in size. This prevents reduction of the chip size. To solve this problem, the joint assignee has already proposed a technique (JP-2004-214020 which is however not intended to be admitted as the prior art in the U.S. statutes). That is, a communication semiconductor integrated circuit device including an oscillator and a counter capable of dividing a frequency of an oscillation signal from the oscillator by a frequency dividing ratio (I+F/G) expressed using an integer part I and a fraction part F/G includes a frequency dividing ratio generator circuit to generate the integer part I and the fraction part F/G according to information regarding a frequency band for use in the IC device, the information being supplied from an external device. The IC device further includes a fractional PLL configured to operate the counter according to a frequency dividing ratio calculated by the frequency dividing ratio generator circuit. By using the fractional PLL as an RF-PLL, the IFVCO to generate a signal of an intermediate frequency is not used in the IC device. The high-frequency IC device using the fractional PLL has an advantage that the IFVCO is not required, but has a drawback that the device size cannot be sufficiently reduced.

For example, JP-A-2002-353843 (Matsushita) describes a technique for a wireless communication device using a VCO shared between a transmitter section and a receiver section. However, the technique of the JP-A is for use with a wireless communication device which differs from that of the present invention in the transmission signal modulation (i.e., the former does not use the offset PLL).

It is therefore an object of the present invention to provide a circuit technique for use in a communication semiconductor integrated circuit (high-frequency IC) device including an offset-PLL transmission circuit in which after an intermediate-frequency signal is modulated through quadrature modulation, the obtained signal is compared in phase with a signal obtained by down-converting a feedback signal of an output transmission signal to thereby control a transmission oscillator circuit. According to the circuit technique, an IFVCO which generates an intermediate-frequency signal is not required and transmission and reception signals of desired frequency bands can be modulated and demodulated without necessitating a complicated frequency division control circuit such as a fractional PLL to reduce the chip size of the high-frequency IC device.

The objects and features of the present invention will become more apparent from the consideration of the following detailed description taken in conjunction with the accompanying drawings.

Representative aspects and features of the invention described in the present application are as below.

That is, in a communication semiconductor integrated circuit device including a transmission circuit of offset Phase-Locked Loop (PLL) type in which an intermediate-frequency signal is modulated by quadrature modulation and is compared in phase with a down-converted signal obtained by down-converting a feedback signal of an output transmission signal to control a transmission oscillator circuit, there is provided a Radio frequency (RF) PLL circuit including an RFVCO which generates a local oscillation signal shared between a transmission circuit and a reception circuit. The RF-PLL circuit includes, as variable frequency dividing circuits capable of conducting frequency dividing operations each using a frequency dividing ratio represented by an integer, a frequency dividing circuit which divides a frequency of a reference oscillation signal and a frequency dividing circuit which divides a frequency of an oscillation signal thereof and feeds back the signal thereto. There is also included a frequency dividing circuit which divides a frequency of a local oscillation signal generated from the RF-PLL circuit to generate an intermediate-frequency signal necessary for the transmission circuit.

According to the circuit configuration described above, only by appropriately changing the frequency dividing ratios of the two variable frequency dividing circuits of the RF-PLL circuit according respectively to the transmission frequency or the reception frequency, a desired intermediate-frequency signal can be generated. Therefore, an IFVCO which generates an intermediate-frequency signal is not required, and the transmission and reception signals in desired frequency bands can be demodulated without requiring a complicated frequency division control circuit like a fractional PLL circuit. As a result, it is possible to reduce the chip size of a communication semiconductor integrated circuit (high-frequency IC) device including an offset-PLL transmission circuit including an RF-PLL.

Other objects, features and advantages of the invention will become apparent from the following description of the embodiments of the invention taken in conjunction with the accompanying drawings.

### BRIEF DESCRIPTION OF THE DRAWINGS

FIG. 1 is a block diagram showing a multiband communication semiconductor integrated circuit (high-frequency IC) device according to the present invention and a first embodiment of a wireless communication system including the same.

FIG. 2 is a diagram to explain a specific example of frequency setting in an RFVCO of the embodiment.

FIG. 3 is a diagram to explain another example of frequency setting in the RFVCO of the embodiment.

FIG. 4 is a block diagram showing a multiband communication semiconductor integrated circuit (high-frequency IC) device according to the present invention and a second embodiment of a wireless communication system including the same.

### DESCRIPTION OF THE EMBODIMENTS

Referring now to the drawings, description will be given of an embodiment of the present invention.

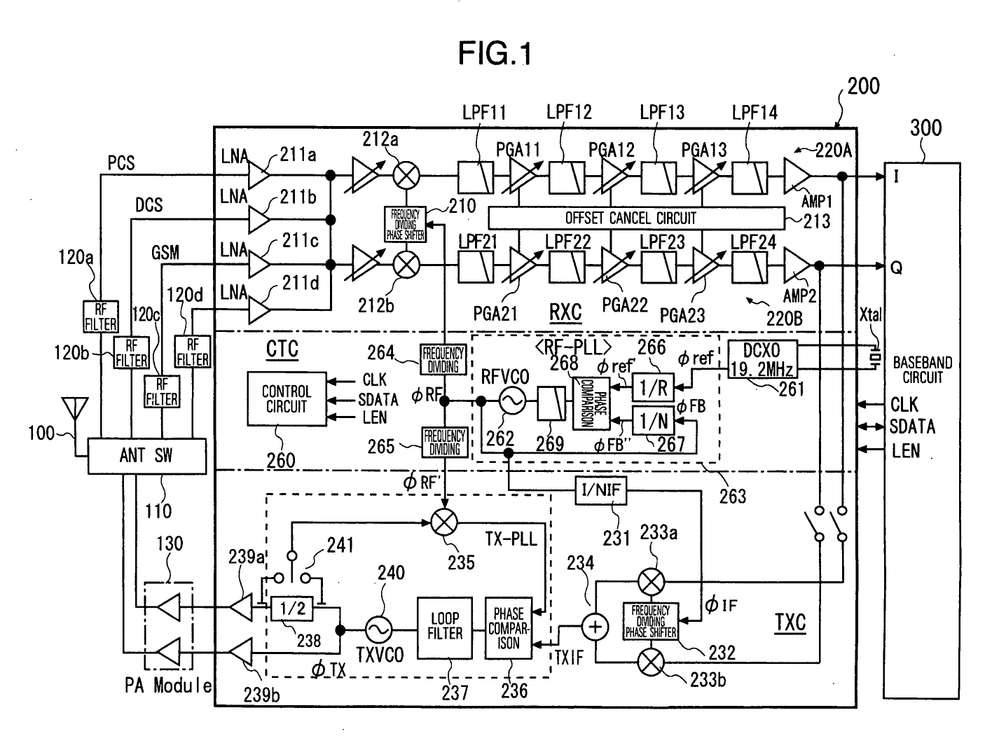

FIG. 1 shows a multiband communication semiconductor integrated circuit (high-frequency IC) device according to the present invention and an example of a wireless communication system including the same.

As can be seen from FIG. 1, the embodiment of a wireless communication system includes a transceiver antenna 100 to transmit and to receive signal radio waves, an antenna switch 110 to conduct change-over between transmission and reception, a radio wave filters 120a to 120d each of which including, for example, a Surface Acoustic Wave (SAW) filter to remove an unnecessary wave from a reception signal, a high-frequency power amplifier circuit (power module) 130, a high-frequency IC device 200 to demodulate a reception signal and to modulate a transmission signal, and a baseband circuit 300 to conduct a baseband process in which an audio signal and a data signal to be transmitted are converted into an I signal of an in-phase component with respect to a fundamental wave and a Q signal of a quadrature component with respect to the fundamental wave and to transmit a signal to control the high-frequency IC device 200.

Although not particularly limitative, the high-frequency IC device 200 of the embodiment is configured to be capable of modulating and demodulating signals of four frequency bands in three communication systems, i.e., GSM850, GSM900, DCS1800, and PCS1900. In association therewith, the high-frequency filters are disposed. That is, the high-frequency IC device 200 includes the filter 120a to pass therethrough a reception signal of the frequency band of PCS1900, the filter 120b to pass therethrough a reception signal of the frequency band of PCS1800, and the filters 120c and 120d pass therethrough reception signals of the GSM frequency bands.

The high-frequency IC device 200 of the embodiment basically includes a reception circuit RXC, a transmission circuit TXC, and control circuit CTC other than RCX and TXC. The CTC includes control circuits and circuits shared between transmission and reception such as a clock generator circuit.

The reception circuit RXC includes low-noise amplifiers 211a to 211d to respectively amplify reception signals of the respective frequency bands of PCS, DCS, and GSM; a frequency dividing phase shifter circuit 210 to divide a frequency of a local oscillation signal φRF generated from a radio-frequency oscillator circuit (RFVCO) 262, which will be described later, to generate a quadrature signal having a phase shift of 90°, mixers 212a and 212b each of which mixes a reception signal amplified by one of the low-noise amplifiers 211a to 211d with the quadrature signal generated from the frequency dividing phase shifter 210 to conduct demodulation and down-conversion of the signal, and high-gain amplifiers 220A and 220B which respectively amplify the demodulated I and Q signals to output the resultant signals to the baseband circuit 300. The reception circuit RXC of the embodiment operates using a direct conversion in which the reception signal is down-converted directly into a signal of a frequency band of a baseband.

The high-gain amplifier 220A is configured such that a plurality of low-pass filter LPFs 11 to 14 are alternately connected to gain control amplifiers PGAs 11 to 13 in series connection and its final stage is connected to an amplifier AMP 1. The amplifier 220A amplifies the demodulated I signal to output the amplified signal to the baseband circuit 300. Similarly, the high-gain amplifier 220B is configured such that a plurality of low-pass filter LPFs 21 to 24 are alternately connected to gain control amplifiers PGAs 21 to 23 in series connection and its final stage is connected to an amplifier AMP 2. The amplifier 220B amplifies the demodulated Q signal to output the amplified signal to the baseband circuit 300. For the amplifiers 220A and 220B, an offset cancel circuit 213 is disposed to cancel an input direct-current (DC) offset of the gain control amplifier PGA.

The control circuit CTC includes a control circuit (control logic) to control the overall operation of the chip, a reference oscillator circuit (DCXO) to generate a reference oscillation signal φref, a radio frequency oscillator circuit (RFVCO) 262 as a local oscillator circuit to generate a radio frequency oscillation signal φRF for frequency conversion, an RF synthesizer 263 to constitute an RF-PLL circuit together with the RFVCO 262, a frequency dividing circuit 264 which divides a frequency of the oscillation signal φRF generated by the RFVCO 262 to supply a resultant signal to the frequency dividing phase shifter 210 of the reception circuit RXC, and a frequency dividing circuit 265 which divides a frequency of the oscillation signal φRF generated by the RFVCO 262 to supply a resultant signal to an offset mixer 235 of the transmission circuit TXC.

The RFVCO 262 includes an oscillator circuit of LC resonance type comprising capacitive elements coupled with respective switching elements in parallel connection. The oscillation frequency of the oscillator circuit is changed to stepwise, by selectively turning the switching elements on using a band change-over signal, the value of each connected capacitive element, i.e., the value of C of the LC resonance circuit is changed. On the other hand, the RFVCO 262, the capacitance value of a variable capacitive element is changed by a voltage from a loop filter 269 of the RF synthesizer 263 to continuously change the oscillation frequency.

Each of the frequency dividing circuit 264 and 265 is controlled by a signal from the control circuit 260 such that the frequency dividing ratio is changed over between a GSM mode to conduct communication in a low band, i.e., in the GSM and a DCS/PCS mode to conduct communication in a high band, that is, in the DCS or the PCS to thereby select a frequency of a signal to be supplied.

The control circuit 260 is being supplied with a synchronizing clock signal CLK, a data signal SDATA, and a load enable signal LEN as a control signal from the baseband circuit 300. When the load enable signal LEN is asserted as an effective level, the control circuit 260 sequentially receives the data signal SDATA sent from the baseband circuit 300 at timing synchronized with the clock signal CLK to generate control signals in the chip in response to a command contained in the data signal SDATA. Although not particularly limitative, the data signal SDATA is serially transmitted.

Since it is required that the frequency of the reference oscillation signal φref generated by the reference oscillator 261 has high precision with respect to a frequency, a crystal vibrator Xtal is externally connected to the oscillator 261. The frequency of signal φref is selected as, for example, 19.2 MHz. The RF synthesizer 263 includes a variable frequency dividing circuit 266 to divide the frequency of the signal φref from the reference oscillator 261 by R (R is a positive integer), a variable frequency dividing circuit 267 to divide the frequency of a feedback signal φFB from the RFVCO 262 by N (N is a positive integer), a phase comparator or detector circuit 268 to compare the phase of the divided signal φref′ with that of the divided signal φFB′ to detect a phase difference therebetween, and a loop filter 269 to generate a voltage corresponding to the output from the phase detector circuit 268.

In the conventional RF-PLL circuit described in EP-A-1,444,784 published 11 Aug. 2004 (JP-A-2003-152535), 26 MHz is selected for the reference oscillation signal φref, the counter 266 divides the frequency of the signal by 65 to obtain a signal of 400 kiloherz (kHz) to be fed to the phase comparator 268. In contrast therewith, in the RF-PLL of the embodiment, 19.2 MHz is selected for the reference oscillation signal φref, the variable frequency dividing circuit 266 divides the frequency of the signal according to a mode (transmission or reception) and a band (for GSM or for DCS or PCS). Specifically, the frequency is divided using a frequency dividing ratio of 44, 46, or 48. The resultant signal is supplied as a reference signal having a variable frequency to the phase comparator circuit 268.

In the embodiment, the frequency dividing ratio R of the variable frequency dividing circuit 266 is set to 44, 46, or 48 to reduce the variable frequency range of the RFVCO. When the range is wide, the size of constituent elements such as a variable capacitive element (varactor diode) becomes large and on-chip elements cannot be used depending on cases. This leads to difficulty in reducing the chip size. However, when the variable frequency range of the RFVCO is narrow, there is obtained an advantage that the chip can be easily reduced in size.

The variable frequency dividing circuit 267 having a frequency dividing ratio represented as 1/N includes a prescaler to divide the frequency of the oscillation frequency signal φRF from the RFVCO 262 and a modulo counter including a first counter (N counter) and a second counter (A counter) to further divide the frequency of the signal divided by the prescaler. The frequency of the oscillation signal is divided by the prescaler and the modulo counter using a known technique (reference is to be made to, for example, EP-A-1,444,784).

In the variable frequency dividing circuit, the prescaler is configured to conduct the frequency division using two mutually different frequency dividing ratios. For example, the counter divides the signal frequency by 47 and 48. In operation, change-over occurs between the ratios in response to a count end signal of the A counter. The N counter and the A counter are programmable counters. The N counter is set an integer part obtained by dividing a desired frequency (desired output of an oscillation frequency fRF of the VCO) by a frequency fref′ of the divided signal φref′ of the reference oscillation signal and the first frequency dividing ratio (e.g., 64) of the prescaler. A remainder of the division (MOD) is set to the A counter. In each of the A and N counters, when the counted value reaches the value set thereto as above, the counter terminates the counting operation and then restarts another counting operation.

Assume in a specific example that when the variable frequency dividing circuit 266 divides the reference oscillation signal φref, the obtained signal φref′ has a frequency fref of 400 kHz and the desired oscillation frequency fRF of the VCO is 3789.6 MHz. Since 3789.6÷0.4=201 . . . 27 (remainder), the value “N” set to the N counter is “201” and the value “A” set to the A counter is “27”. With the counters N and A set as above, when the prescaler and the modulo counter operate, the prescaler first divides by 47 the oscillation signal φFB from the RFVCO 262. The A counter counts the number of outputs from the RFVCO 262. When the count reaches “27”, the A counter outputs a count end signal. In response thereto, a change-over operation takes place for the operation of the prescaler. That is, the frequency dividing ratio is changed to “48”. Thereafter, until count value of the A counter reaches “27” again, the prescaler divides by 48 the oscillation signal from the RFVCO 262.

By conducting the above operation, the modulo counter can divide the frequency of the oscillation signal using a ratio of a number including a fractional part, not a ratio of an integer. In the PLL circuit of the embodiment, the RFVCO 262 is controlled for its oscillation. That is, a feedback operation is conducted for the reference oscillation signal of a frequency indicated by an output from the N count to match the frequency with the frequency fref′ (400 kHz) of the divided signal φref′. Therefore, in the specific example in which “N” to be set to the N counter is “201” and “A” to be set to the N counter is “27”, the oscillation frequency fRF of the VCO 262 is obtained as 3789.6 MHz as below.

$$\begin{matrix}fRF = ( 47 \times 201 + 27 ) \times {fref}^{′} \\ = 9474 \times 400 \\ = 3789600\end{matrix}$$

Since the N and A counters are configured using binary counters in an actual circuit system, the value “N” to be set to the N counter and the value “A” to be set to the N counter are binary values. The control circuit 260 generates the values “N” and “A” according to band information and channel information from the baseband circuit 300 to supply the values to the N and A counters, respectively.

The transmission circuit TXC includes a frequency dividing circuit 231 to divide the frequency of the oscillation signal φRF generated by the RFVCO 262 to generate an oscillation signal φIF having an intermediate frequency, a frequency dividing phase shifter circuit 232 to divide the signal divided by the circuit 231 to generate a quadrature signal having a phase shifted 90° from that of the original signal, modulator circuits 233a and 233b to modulate the quadrature signal from the circuit 232 using the I and Q signals supplied from the baseband circuit 300, an adder 234 to add the modulated signals to each other, a transmission oscillator TXVCO 240 to generate a transmission signal φTX having a predetermined frequency, an offset mixer 235 which mixes a feedback signal obtained from the output port of the transmission oscillator TXVCO 240 with a φRF′ obtained by dividing the high-frequency oscillation signal φRF from the high-frequency oscillator RFVCO 262 to generate a signal having a frequency corresponding to the frequency difference therebetween, a phase comparator circuit 236 to compare an output signal from the offset mixer 235 with a signal TXIF obtained from the adder 234 to detect the phase difference therebetween, a loop filter 237 to generate a voltage corresponding to an output from the phase detector circuit 236, a frequency dividing circuit 238 to divide an output from the transmission oscillator TXVCO 234 to generate a transmission signal of GSM, and transmission output buffer circuits 239a and 239b.

The transmission circuit of the embodiment uses an offset PLL system in which an intermediate-frequency carrier is quadrature-modified using the transmission I and Q signals and a feedback signal from the output port of the TXVCO 240 is mixed with the signal φRF′ obtained by dividing the high-frequency signal φRF from the RFVCO 262 to down-convert the signal into a signal having an intermediate frequency corresponding to the frequency difference (offset) therebetween. The signal is then compared in phase with the signal after the quadrature conversion to control the TXVCO 240 according to the phase difference therebetween. The phase detector circuit 236, the loop filter 237, the TXVCO and the offset mixer 235 configure a transmission PLL (TX-PLL) circuit to conduct the frequency conversion (up-converting). The system configuration also includes a switch 241 to determine a position to obtain the signal to be fed back to the offset mixer 235. Specifically, the switch 241 conducts a change-over operation between the output port of the TXVCO 240 and that of the frequency dividing circuit 238 depending on whether the system is in the GSM mode or the DCS/PCS mode. In the GSM mode, the switch 241 selects the output port of the frequency dividing circuit 238.

In the multiband wireless communication system of the embodiment, the control circuit 260 sets in response to an instruction from, for example, the baseband circuit 300 the frequency dividing ratios R and N of the RF-PLL circuit according to the band and channel information used for transmission. Additionally, the control circuit changes the frequency dividing ratios respectively in the GSM mode and the DCS/PCS mode. This resultantly changes the frequencies of the oscillation signals supplied to the reception circuit RXC and the transmission circuit TXC to thereby change the frequencies for signal transmission and reception.

The oscillation frequency of the RFVCO 262 is set to different values between the reception and transmission modes, as well as between the GSM 850 and the GSM 900, and between the DCS and PCS modes. In the GSM, the generated oscillation signal φRF is divided by two by the frequency dividing circuit 264 and is fed to the frequency dividing phase shifter circuit 210. In the DCS and PCS modes, the signal φRF is supplied directly to the circuit 210. In the GSM, the signal φRF from the RFVCO 262 is divided by four by the frequency divider circuit 265 and is supplied as φRF′ to the offset mixer 235. In the DCS and PCS modes, the signal φRF is divided by two by the circuit 265 and is supplied as φRF′ to the offset mixer 235.

The offset mixer 235 generates a difference signal corresponding to the frequency difference (fRF′−fTX) between φRF′ and the transmission oscillation signal φTX from the TXVCO 240 and delivers the signal to the phase comparator circuit 236. The transmission PLL (TX-PLL) circuit operates to match the frequency of the difference signal with that of the modulated signal TXIF. In other words, the TXVCO 240 is controlled to oscillate at a frequency corresponding to the difference between the frequency (fRF/4 or fRF/2) of the oscillation signal φRF′ from the RFVCO 262 and the frequency (fTX) of the modulated signal TXIF.

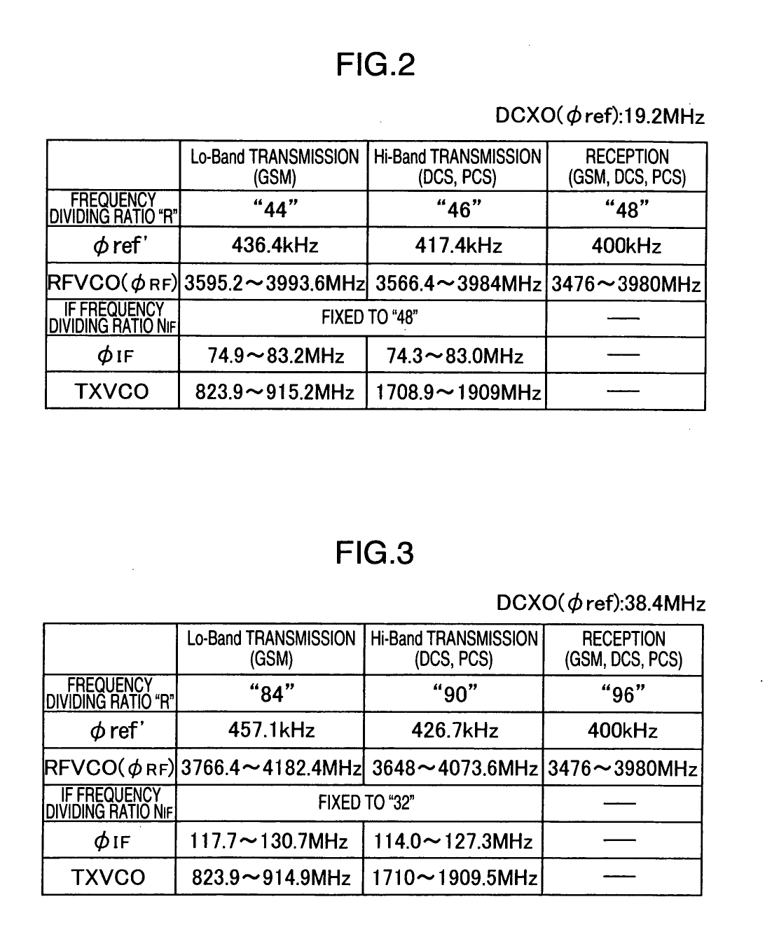

Referring next to FIG. 2, description will be given of a specific example of value setting in the RFVCO 262 in the embodiment of the wireless communication system.

In the example, a frequency of 19.2 MHz is selected as the reference oscillation frequency of the oscillation signal φref generated by the reference oscillator DCXO 261, and the frequency dividing ratio “R” of the variable frequency dividing circuit 266 to divide the frequency of the signal φref is set to “44” for low-band transmission, “46” for high-band transmission, and “48” for reception regardless of the band used for the reception. As a result, the frequency of the reference signal φref′ supplied to the frequency dividing phase shifter 268 is 436.4 kHz, 417.4 kHz, and 400 kHz in the respective operations.

For the oscillation signal φRF generated from the high-frequency oscillator RFVCO 262, the frequency dividing ratio “N” of the variable frequency dividing circuit 267 to divide the frequency of the signal φRF according to the band to be used and the channel information is set such that the frequency is selected from a frequency range from 3566.4 MHz to 3993.6 MHz for transmission and from a frequency range from 3476 MHz to 3980 MHz for reception. The overall variable frequency range of the oscillator RFVCO 262 is 417.6 (3993.6−3476) MHz. Therefore, it is required for the RFVCO 262 to have a variable oscillation frequency range of at least 13.9%.

The frequency dividing ratio NIF of the frequency divider 231 to generate an intermediate-frequency signal φIF is set to “48”. Therefore, the frequency fIF of the signal φIF is set to a range from 74.9 MHz to 83.2 MHz for low-band transmission and a range from 74.3 MHz to 83.0 MHz for high-band transmission. The frequency dividing ratio of the frequency divider 265 is set to “4” for low-band transmission and “2” for high-band transmission. Since the circuits 231 and 265 divide the frequency of the same signal φRF, the signals supplied from the RFVCO via the circuit 265 to the offset mixer 235 have frequencies of 12 fIF and 24 fIF.

The frequency of the output signal from the offset mixer 235 is substantially equal to the frequency difference between the transmission signal and the signal from the frequency divider 265, that is, the frequency fIF of the intermediate-frequency signal φIF. That is, fTX+fIF=12 fIF and fTX+fIF=24 fIF. Therefore, fTX=11 fIF and fTX=23 fIF. As a result, the frequency fTX of the transmission signal for low-band transmission ranges from 823.9 to 915.2 MHz and that of the transmission signal for high-band transmission ranges from 1708.9 to 1909 MHz.

Next, referring to FIG. 3, description will be given of another specific example of value setting in the RFVCO 262 in the embodiment of the wireless communication system.

In the example, a frequency of 38.4 MHz is selected as the reference oscillation frequency of the oscillation signal φref generated by the reference oscillator 261, and the frequency dividing ratio “R” of the counter 266 to divide the frequency of the signal φref is set to “84” for low-band transmission, “90” for high-band transmission, and “96” for reception regardless of the band used for the reception. As a result, the frequency of the reference signal φref′ supplied to the frequency dividing phase shifter 268 is 457.1 kHz, 426.7 kHz, and 400 kHz in the respective operations.

For the oscillation signal φRF generated from the high-frequency oscillator RFVCO 262, the frequency dividing ratio “N” of the counter 266 to divide the frequency of the signal φRF according to the band to be used and the channel information is set such that the frequency is selected from a frequency range of 3648.0 MHz to 4182.4 MHz for transmission and from a frequency range of 3476 MHz to 3980 MHz for reception. The overall variable frequency range of the oscillator RFVCO 262 is 706.4 (4182.4−3476) MHz. Therefore, it is required for the RFVCO 262 to have a variable oscillation frequency range of at least 18.4%.

The frequency dividing ratio NIF of the frequency divider 231 to generate an intermediate-frequency signal φIF is set to “32”. Therefore, the frequency fIF of the signal φIF is set to a range of 117.7 MHz to 130.7 MHz for low-band transmission and a range of 114.0 MHz to 127.3 MHz for high-band transmission. The frequency dividing ratio of the frequency divider 265 is set to “4” for low-band transmission and “2” for high-band transmission. The signals supplied to the offset mixer 235 have frequencies of 8 fIF and 16 fIF.

The frequency of the output signal from the offset mixer 235 is substantially equal to the frequency difference between the transmission signal and the signal from the frequency divider 265, that is, the frequency fIF of the intermediate-frequency signal φIF. That is, fTX+fIF=8 fIF and fTX+fIF=16 fIF. Therefore, fTX=7 fIF and fTX=15 fIF. As a result, the frequency fTX of the transmission signal for low-band transmission ranges from 823.9 to 914.9 MHz and that of the transmission signal for high-band transmission ranges from 1710 to 1909.5 MHz.

The counters 266 and 267 and the IF frequency divider circuit 232 of the RF-PLL may also be configured to conduct the frequency dividing operation using the frequency dividing ratio of the first frequency plan (FIG. 2) and that of the second frequency plan (FIG. 3). As a result, the oscillation signals respectively of 19.2 MHz and 38.4 MHz can be used as the reference oscillation signal φref. This advantageously improves usability and operability for the user.

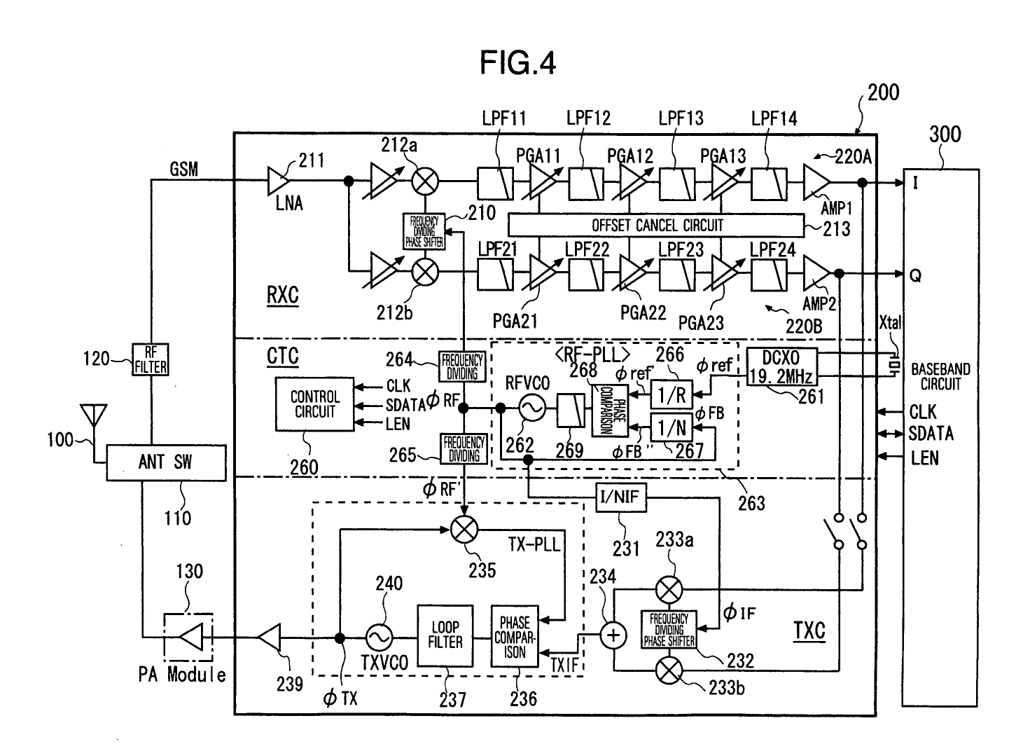

FIG. 4 shows a multiband communication semiconductor integrated circuit (high-frequency IC) device according to the present invention and a second embodiment of a wireless communication system including the same. As can be seen from FIG. 4, the embodiment includes a high-frequency IC device capable of conducting signal communication of a single-band system, i.e., a communication system such as the GSM and a wireless communication system including the same.

It can be readily understood by comparing FIG. 4 with FIG. 1 showing a multiband high-frequency IC device and a wireless communication system including the same that the present embodiment includes only one set of a high-frequency filter 120 and a low-noise amplifier 211 on the reception circuit side and only one transmission buffer circuit 239 on the transmission circuit side. The frequency dividing circuit 238 is removed from the succeeding stage of the TXVCO 240. In the configuration, the frequency divider circuits 264 and 265 to divide the frequency of the oscillation signal φRF from the RFVCO 262 to supply the signal to a mixer 212 on the reception side and to an offset mixer 235 on the transmission side conduct the frequency division using fixed frequency dividing ratios.

Although not particularly limitative, a phase comparator circuit 268 of the RF-PLL 263 of the embodiment includes a digital phase comparator circuit, and a phase comparator circuit 236 of the transmission PLL circuit includes a digital phase comparator circuit and analog phase comparator circuit in parallel connection. In the configuration, a change-over operation can be conducted between the high-speed digital phase comparator circuit and the high-precision analog phase comparator circuit. The other configurations are the same as those of the first embodiment shown in FIG. 1.

Also in the present embodiment, the reference oscillator circuit 261 generates a reference oscillation signal φref having a frequency of 19.2 MHz or 38.4 MHz. The frequency plan established using parameters such as the frequency of the signal from the RFVCO 2262, the frequency dividing ratio “R” of the counter 266 in the RF-PLL, and the frequency dividing ratio NIF of the frequency dividing circuit 231 to generate an intermediate-frequency signal φIF can be determined in a similar manner as for the first embodiment and hence detailed description thereof will be avoided.

Although the present invention has been described in detail according to embodiments thereof, but the present invention is not restricted by those embodiments. It is to be appreciated that the embodiments can be modified in various ways without departing from the scope and spirit of the present invention. For example, in the description of the embodiments, the frequency dividing ratio NIF of the IF frequency divider 231 to generate an intermediate-frequency signal φIF is fixed. However, the system may be configured such that the ratio NIF can be changed between, for example, “47”, “48”, and “49”. This advantageously prevents higher harmonics of the signal φIF from entering in a range of the reception frequency band.

When higher harmonics of the signal φIF are in the range of the reception frequency band, higher harmonics of the signal φIF pass through the mixer 233 for modulation and the transmission VCO 240 to resultantly appear as spurious signals on the output port. This increases the quantity of leakage of signals into the reception frequency band and leads to a fear that the reception band noise is beyond the designated or specified range. In this situation, the problem of signal leakage into reception frequency band can be avoided by changing the frequency dividing ratio NIF of the IF frequency divider 231 such that frequencies of higher harmonics of the signal φIF are outside the range of the reception frequency band. This applies also to the frequency dividing circuit 266 to divide the reference oscillation signal φref.

Additionally, the frequency of the reference oscillation signal φref is selected as 19.2 MHz or 38.4 MHz in the embodiments. However, this does not restrict the present invention. It is also possible to use other frequencies such as 26 MHz and 13 MHz by appropriately setting the frequency dividing ratios R and N respectively of the counters 266 and 267 in the RF-PLL and the frequency dividing ratio NIF of the IF frequency dividing circuit 231. However, in the portable telephone of the Wide-band CDMA (WCDMA) system practically used today in Japan, the frequency of the reference oscillation signal φref is 19.2 MHz in many cases. In this situation, by selecting 19.2 MHz or 38.4 MHz as in the embodiments, it is advantageously possible to provide a high-frequency IC device to easily configure a multiband portable telephone capable of conducting the GSM communication and the WCDMA communication.

In the description of the embodiments, according to the band information and the channel information supplied from the baseband circuit 300, the control circuit 260 generates the setting code “N” or “A” to be fed to the variable frequency dividing circuit 267 in the RF-PLL. However, in place of the band information and the channel information, it is also possible by receiving information of frequencies to be used, the high-frequency IC device generates, according to the frequency information, the setting code to be fed to the variable frequency dividing circuit 267. In the embodiment, the high-frequency IC device incorporates the oscillation circuit including only the crystal vibrator as an external element. However, it is also possible that the high-frequency IC device receives a reference oscillation signal φref of a predetermined frequency (19.2 MHz or 38.4 MHz) from another IC device such as an oscillation module or a baseband IC device as a discrete device.

Description has been given of a case in which the present invention is applied to a quad-band system capable of conducting the four-band communication according to three communication systems, i.e., GSM850, the GSM900, and the DCS1800/PCS1900 and to a single-band system capable of conducting only the GSM communication. However, the present invention is applicable also to a dual-band system capable of conducting communication in the GSM and the DCS or in the GSM and PCS, a triple-band system capable of conducting communication in the GSM, the DCS, and the PCS, and a system capable of additionally conducting the WCDMA communication.

It should be further understood by those skilled in the art that although the foregoing description has been made on embodiments of the invention, the invention is not limited thereto and various changes and modifications may be made without departing from the spirit of the invention and the scope of the appended claims.

1. A communication semiconductor integrated circuit device, comprising:
a transmission circuit of offset phase-locked loop (PLL) type in which an intermediate-frequency signal is modulated by quadrature modulation and is compared in phase with a down-converted signal obtained by down-converting a feedback signal of an output transmission signal to control a transmission oscillator circuit;
a receiving circuit which demodulates a reception signal using an oscillation signal of a predetermined frequency; and
a radio frequency (RF) PLL circuit including a high-frequency oscillator circuit which generates an oscillation signal shared between the transmission circuit and the reception circuit, wherein:
the RF-PLL circuit comprises a first variable frequency-dividing circuit which divides a frequency of a reference oscillation signal, a second variable frequency-dividing circuit which divides a frequency of an oscillation signal from the high-frequency oscillator circuit and feeding back the signal thereto, and a phase-difference detector circuit which generates a voltage corresponding to a phase difference between the signal divided by the first variable frequency-dividing circuit and that divided by the second variable frequency-dividing circuit, thereby controlling the oscillation frequency of the high-frequency oscillator circuit according to an output from the phase-difference detector circuit, the integrated circuit device further comprising a first frequency dividing circuit for dividing a frequency of an oscillation signal generated from the RF-PLL circuit to generate an intermediate-frequency (IF) signal necessary for the transmission circuit,
a frequency dividing ratio of the first variable frequency-dividing circuit and a frequency dividing ratio of the second variable frequency-dividing circuit being changeable according to a transmission frequency or a reception frequency.

2. A communication semiconductor integrated circuit device according to claim 1, wherein each of the first and second variable frequency-dividing circuits conducts a frequency dividing operation using a frequency dividing ratio represented by an integer.

3. A communication semiconductor integrated circuit device according to claim 1, further comprising:
a frequency converting circuit which combines the feedback signal of the output transmission signal with an oscillation signal of a predetermined frequency to thereby down-convert the signal; and
a second frequency dividing circuit which divides a frequency of an oscillation signal generated from the high-frequency oscillator circuit to generate the oscillation signal of the predetermined frequency to be supplied to the frequency converting circuit, wherein
the frequency dividing ratio of the second frequency dividing circuit is changed according to a frequency band used by the transmission circuit for transmission.

4. A communication semiconductor integrated circuit device according to claim 1, wherein the frequency dividing ratios of the first and second variable frequency-dividing circuits are changed according to a frequency band used for transmission or reception.

5. A communication semiconductor integrated circuit device according to claim 1, wherein the frequency dividing ratio of the first frequency dividing circuit is fixed.

6. A communication semiconductor integrated circuit device according to claim 1, wherein the frequency dividing ratios of the first and second variable frequency-dividing circuits are variable, and a plurality of reference oscillation signals having mutually different oscillation frequencies are available.

7. A communication semiconductor integrated circuit device according to claim 1, wherein:
the frequency of the reference oscillation signal is 19.2 MHz; and
the frequency dividing ratio of the first frequency dividing circuit is “48”.

8. A communication semiconductor integrated circuit device according to claim 7, wherein the frequency dividing ratio of the first variable frequency dividing circuit is selected from “44”, “46”, and “48”.

9. A communication semiconductor integrated circuit device according to claim 1, wherein:
the frequency of the reference oscillation signal is 38.4 MHz; and
the frequency dividing ratio of the first frequency dividing circuit is “32”.

10. A communication semiconductor integrated circuit device according to claim 9, wherein the frequency dividing ratio of the first variable frequency dividing circuit is selected from “84”, “90”, and “96”.

11. A communication semiconductor integrated circuit device according to claim 3, further comprising a third frequency dividing circuit which divides a frequency of an oscillation signal generated from the RF-PLL circuit to supply a divided signal resultant from the frequency division to the receiving circuit.
